(19) United States
(12) Patent Application Publication
(10) Pub. No.: US 2009/0075401 A1
(43) Pub. Date: Mar. 19, 2009

(54) METHOD FOR MANUFACTURING FERROELECTRIC CAPACITOR AND METHOD FOR MANUFACTURING FERROELECTRIC MEMORY DEVICE

(75) Inventor: Hiroaki Tamura, Shimosuwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/192,185

(22) Filed: Aug. 15, 2008

(30) Foreign Application Priority Data
Sep. 19, 2007 (JP) 2007-242464

(51) Int. Cl. H01L 21/02

(52) U.S. Cl. 438/3; 257/E21.009

(57) ABSTRACT

A method for manufacturing a ferroelectric capacitor having a ferroelectric film interposed between a first electrode and a second electrode is provided. The method includes the steps of: forming an electrode film above a substrate; thermally oxidizing a surface layer of the electrode film to form an oxidized electrode layer in an atmosphere of atmospheric-pressure with an oxygen partial pressure being 2% or grater; forming a ferroelectric film on the electrode layer by a MOCVD method thereby forming a first electrode composed of the electrode film including the oxidized electrode layer that serves as a base for the ferroelectric film; and forming a second electrode on the ferroelectric film.

The entire disclosure of Japanese Patent Application No. 2007-242464, filed Sep. 19, 2007 is expressly incorporated by reference herein.

### BACKGROUND

1. Technical Field

The present invention relates to a method for manufacturing ferroelectric capacitors and a method for manufacturing ferroelectric memory devices.

2. Related Art

Ferroelectric memories (FeRAM) are nonvolatile memories capable of low voltage and high-speed operation, using spontaneous polarization of ferroelectric material, and their memory cells can be each formed from one transistor and one capacitor (1T/1C). Accordingly, ferroelectric memories can achieve integration at the same level of that of DRAM, and are therefore expected as large-capacity nonvolatile memories. As the ferroelectric material, perovskite type oxides such as lead zirconate titanate (Pb (Zi, Ti) O₃: PZT), and bismuth layered compounds such as strontium bismuth tantalate (SrBi₂TaO₉: SBT) can be used.

In order to make the aforementioned ferroelectric material exhibit its maximum ferroelectric characteristic, its crystal orientation is extremely important. For example, when PZT is used as the ferroelectric material, a predominant orientation exists depending on its crystal system. Generally, when PZT is used in memory devices, titanium-rich compositions that contain a greater amount of Ti (titanium) compared to Zr (zirconium) is used in order to obtain greater spontaneous polarization. In such a composition range, PZT belongs to a tetragonal system, and its spontaneous polarization axis aligns with the c-axis. In this case, ideally, the maximum polarization can be obtained by orienting it in the c-axis, which is in effect very difficult, and a-axis orientation components perpendicular to the c-axis concurrently exist. It is noted that because the a-axis orientation components do not contribute to polarization inversion, the ferroelectric characteristic may be impaired.

In this respect, it has been conceived to orient the a-axis in a direction offset at a predetermined angle from the substrate normal line by making the crystal orientation of PZT to a (111) orientation. As a result, the polarization axis has a component in the substrate normal line direction, and thus can contribute to polarization inversion. On the other hand, the c-axis orientation component concurrently has its polarization axis oriented to a predetermined offset angle with respect to the substrate normal line direction, such that a certain amount of loss occurs in the amount of surface charge induced by polarization inversion. However, the entire crystal components can be made to contribute to polarization inversion, such that the charge retrieving efficiency significantly excels, compared to the case of the c-axis orientation.

As a method for forming a ferroelectric film with its PZT crystal orientation aligned in [111] direction, a method described in Japanese Laid-open Patent Application JP-A-2003-324101 may be used. According to the method described in the aforementioned document, a lower electrode with a (111) crystal orientation is formed from iridium, a surface layer on its upper surface side is thermally oxidized to form an iridium oxide layer, and then a ferroelectric film is formed on the iridium oxide layer. At the time of forming the ferroelectric film, a MOCVD method is used, in which source material gas for the ferroelectric film and oxygen gas are chemically reacted for forming the film. According to this method, the film formation is conducted with a smaller amount of oxygen gas than the amount of oxygen gas necessary for the chemical reaction, and then the film formation is further conducted with an amount of oxygen gas greater than the amount of oxygen gas necessary for the chemical reaction. Although details of the mechanism thereof are not clarified, the iridium oxide layer contributes to determination of growth orientation of PZT, and makes PZT mainly orient to [111].

By the method described in the aforementioned document, the crystal orientation of PZT may be improved, but the method entails some points to be improved in order to improve the characteristics of the ferroelectric film. More specifically, according to the method described in the aforementioned document, a surface layer (iridium) of the lower electrode is oxidized to form an iridium oxide layer under a reduced pressure in a film forming chamber of the MOCVD apparatus that is used for forming a ferroelectric film. Accordingly, the condition for forming the iridium oxide layer is restricted by the condition for forming the ferroelectric film and/or the performance of the MOCVD apparatus, such that the iridium oxide layer may not be formed under an optimum condition.

Some of the specific factors that restrict the condition for forming the iridium oxide layer may be that the oxygen partial pressure in the film forming chamber cannot be set higher because the ferroelectric film is to be formed under a reduced pressure, the time for oxidizing iridium cannot be set longer in view of the throughput, and the oxidizing temperature is fixed at the film forming temperature of the ferroelectric film, and the like. Under these restrictions, oxidation of iridium may not be sufficient and/or may not be uniform due to the shortage of the oxygen partial pressure and oxidation time, such that the volume expansion due to oxidation becomes non-uniform and protrusions (hillocks) in colonies would likely form on the iridium oxide layer. The hillocks on the iridium oxide layer would cause roughness in the surface morphology of the ferroelectric film, poor crystal orientation of the ferroelectric film and the like, and present hindrance to the improvement of the characteristics of the ferroelectric film.

### SUMMARY

In accordance with an advantage of some aspects of the invention, there is provided a method for effectively manufacturing ferroelectric capacitors with favorable characteristics and ferroelectric memory devices equipped with the ferroelectric capacitors.

In accordance with an embodiment of the invention, a method for manufacturing a ferroelectric capacitor having a ferroelectric film interposed between a first electrode and a second electrode, the method including the steps of: forming an electrode film above a substrate; thermally oxidizing a surface layer of the electrode film to form an oxidized electrode layer in an atmosphere of atmospheric-pressure with an oxygen partial pressure being 2% or grater; forming a ferroelectric film on the electrode layer by a MOCVD method thereby forming a first electrode composed of the electrode film including the oxidized electrode layer that serves as a base for the ferroelectric film; and forming a second electrode on the ferroelectric film.

Thermal oxidation of a surface layer of the electrode film in an atmosphere of atmospheric-pressure makes easier the pressure control within the chamber where the thermal oxidation is conducted, compared to thermal oxidation under a reduced pressure. Therefore, it is not necessary to use a chamber that has a high degree of air-tightness and endures a low pressure, such that the thermal oxidation step can be conducted in a large-sized chamber. Accordingly, many substrates having electrode films formed thereon can be subjected to thermal oxidation treatment in a batch, and therefore ferroelectric capacitors can be effectively manufactured.

The inventors of the invention conducted experiments while changing oxygen partial pressure to examine conditions in which hillocks are generated in oxidized electrode layers. As a result, it was found that hillocks would not be generated in the oxidized electrode layers when the oxygen partial pressure is 2% or greater. Accordingly, by setting the oxygen partial pressure at 2% or greater, favorable oxidized electrode layers can be formed, and favorable ferroelectric films can be formed thereon.

It is noted that, in accordance with the invention, the oxygen partial pressure Po₂ (%) is defined by the following formula:

Po₂=(p/760)·(fo₂/fₜₒₜₐₗ)·100, where p is the pressure inside the chamber (Torr), fo₂ is the flow quantity of oxygen gas supplied to the chamber (sccm), and fₜₒₜₐₗ is the total amount of gases supplied to the chamber (sccm). Also, the atmosphere of atmospheric-pressure means a pressure atmosphere in which the pressure is not reduced for thermal oxidation.

Furthermore, in the step of forming a ferroelectric film, the ferroelectric film may preferably be formed by using a MOCVD method that reacts source material gas for the ferroelectric film and oxygen gas, wherein an initial film is formed in an atmosphere that contains the oxygen gas in an amount less than an amount necessary for reaction of the source material gas, and then a core film is formed in an atmosphere that contains the oxygen gas in an amount greater than an amount necessary for reaction of the source material gas, thereby forming the ferroelectric film composed of the initial film and the core film.

As a result, the initial film has a favorable crystal orientation as its growth direction is optimized by the oxidized electrode layer. Therefore, the core film can be formed epitaxial-like on the initial film having a favorable crystal orientation, such that the core film has a favorable crystal orientation. Accordingly, the ferroelectric film composed of the initial film and the core film can be formed with a favorable crystal orientation.

It is noted that, in the present embodiment, the amount of oxygen gas necessary for reaction of the source material gas is the sum of the amount of oxygen required for burning carbon and hydrogen originated from the source material gas and releasing them as CO₂ (carbon dioxide) and H₂O (water), and the amount of oxygen required for crystallizing ferroelectric materials composing the ferroelectric film.

Furthermore, in the step of forming an electrode film, the electrode film may preferably be formed to have a (111) crystal orientation. As a result, the crystal orientation of the ferroelectric film can be set to a (111) crystal orientation as the crystal orientation of the electrode film is reflected therein. The ferroelectric film with a (111) crystal orientation can achieve a favorable charge retrieving efficiency, and therefore has excellent ferroelectric characteristics.

Furthermore, in the step of forming an electrode film, the electrode film may preferably be formed from iridium. Iridium is thermally and chemically stable, and therefore can make the electrode film highly reliable. Also, iridium oxide, that is an oxide of iridium, is electrically conductive, and therefore can make the first electrode function as an electrode even when it has oxidized portions.

Also, in the step of forming a ferroelectric film, the ferroelectric film composed of Pb (Zr, Ti) O₃ may preferably be formed. Pb (Zr, Ti) O₃ (lead zirconate titanate: PZT) is well known as a ferroelectric material, such that a highly reliable ferroelectric film can be formed.

The thermal oxidation step may preferably be conducted by furnace annealing, and in this case, the surface layer of the ferroelectric film may preferably be heated to 550° C. or higher in an oxygen atmosphere. With the furnace annealing, the degree of freedom in setting conditions such as heating temperature, oxygen partial pressure, oxidation time and the like is increased, whereby the surface layer of the electrode film can be thermally oxidized under an optimum condition. In particular, by heating the surface layer of the electrode film at 550° C. or higher in an oxygen atmosphere, the oxidized electrode layer can be formed well. It is noted that the oxygen atmosphere here means an atmosphere in which nothing other than oxygen gas is supplied, and is an atmosphere in which the oxygen partial pressure defined by the aforementioned formula is generally 100%.

In the thermal oxidation step, the oxidized electrode layer may preferably be formed to a thickness of 30 nm or less. As a result, the crystal orientation of the electrode film can be reflected in a crystal growth direction of the ferroelectric film through the oxidized electrode layer, and therefore the ferroelectric film with favorable crystal orientation can be formed.

A method for manufacturing a ferroelectric memory device in accordance with an embodiment of the invention pertains to a method for manufacturing a ferroelectric memory device equipped with a ferroelectric capacitor, and a transistor that switches an electrical signal to be transmitted to the ferroelectric capacitor, wherein the ferroelectric capacitor is manufactured by the method for manufacturing a ferroelectric capacitor described above. As a result, favorable ferroelectric capacitors can be effectively manufactured as described above, such that highly reliable ferroelectric memory devices that have reduced bit defects can be effectively manufactured.

### BRIEF DESCRIPTION OF THE DRAWINGS

FIG. 1 is a side cross-sectional view of a ferroelectric memory device manufactured by a manufacturing method in accordance with an embodiment of the invention.

FIGS. 2A-2D are cross-sectional views showing steps of a method for manufacturing a ferroelectric memory device in accordance with an embodiment of the invention.

FIGS. 3A-3D are cross-sectional views showing steps of the method for manufacturing a ferroelectric memory device in accordance with the embodiment of the invention.

FIG. 4 is a graph showing relations between oxygen partial pressures and generation of hillocks.

FIG. 5 is a graph that compares X-ray diffraction patterns of an example of the embodiment and an example of related art.

FIG. 6 is a graph that compares electric characteristics of examples of the embodiment and an example of related art.

FIG. 7 is a graph that compares electric characteristics of examples of the embodiment and an example of related art.

FIGS. 8A and 8B are graphs that compare saturation characteristics of examples of the embodiment and an example of related art.

### DESCRIPTION OF EXEMPLARY EMBODIMENTS

A preferred embodiment of the invention is described below, but the technical scope of the invention is not limited to the embodiment described below. In the description, various structures are exemplified using drawings. However, it is noted that the measurement and scale of each of the structural members may be made different from those of the actual structure in each of the figures such that characteristic portions of each of the structures can be readily understood.

Ferroelectric Memory Device

First, an example of a ferroelectric memory device that is manufactured by a manufacturing method in accordance with an embodiment of the invention is described.

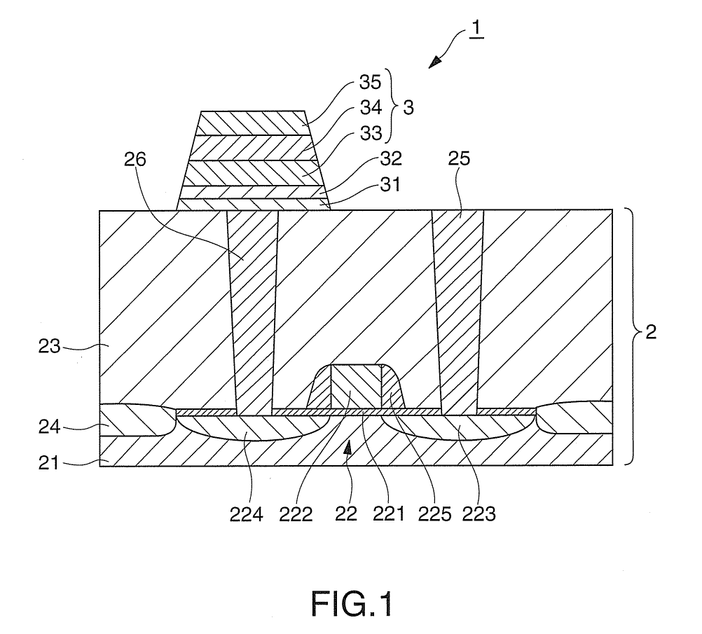

FIG. 1 is a cross-sectional view of a main portion of a ferroelectric memory device 1 in accordance with an embodiment example. As shown in FIG. 1, the ferroelectric memory device 1 has a stacked type structure, and is equipped with a base substrate 2 having a transistor 22, and a ferroelectric capacitor 3 formed on the base substrate 2.

The base substrate 2 is equipped with a silicon substrate (substrate) 21 comprised of, for example, single crystal silicon, the transistor 22 provided thereon, and a base dielectric film 23 comprised of SiO₂ that covers the transistor 22. Element isolation regions 24 are provided in the surface layer of the silicon substrate 21, wherein an area between the element isolation regions 24 corresponds to each of the memory cells.

The transistor 22 is formed from a gate dielectric film 221 provided on the silicon substrate 21, a gate electrode 222 provided on the gate dielectric film 221, a source region 223 and a drain region 224 provided on both sides of the gate electrode 222 in a surface layer of the silicon substrate 21, and a side wall 225 provided on a side surface of the gate electrode 222. In the present example, a first plug 25 that conductively connects to the source region 223 is provided on the source region 223, and a second plug 26 that conductively connects to the drain region 224 is provided on the drain region 224.

The first plug 25 and the second plug 26 are formed from a conductive material, such as, for example, W (tungsten), Mo (molybdenum), Ta (tantalum), Ti, Ni (nickel) or the like. The first plug 25 is electrically connected to a bit line (not shown) in the present example, and the source region 223 and the bit line are conductively connected through the first plug 25.

The ferroelectric capacitor 3 is formed on a conductive film 31 and an oxygen barrier film 32 that are successively formed on the base dielectric film 23 and the second plug 26 in the present example, and has a structure in which a lower electrode (first electrode) 33, a ferroelectric film 34 and an upper electrode (second electrode) 35 are laminated in this order from the lower layer. The lower electrode 33 is electrically connected to the second plug 26 through the oxygen barrier film 32 and the conductive film 31. In other words, the lower electrode 33 is conductively connected with the drain region 224.

The conductive film 31 is comprised of a conductive material, such as, for example, TiN. The oxygen barrier film 32 is comprised of a conductive material having oxygen barrier property, such as, for example, TiAlN, TiAl, TiSiN, TiN, TaN, TaSiN and the like. Also, the conductive film 31 and the oxygen barrier film 32 may preferably be comprised of a material containing Ti that particularly excels in self-orienting property, whereby the lower electrode 33 and the ferroelectric film 34 can be formed with favorable crystal orientation.

The lower electrode 33 is formed from a single layer film or a multilayer film of laminated plural layers, and a film composed of at least one of iridium, Pt (platinum), Ru (ruthenium), Rh (rhodium), Pd (palladium) and Os (osmium), an alloy thereof, or an oxide thereof may be used. In the present example, the lower electrode 33 composed of a single layer of an iridium film showing a (111) crystal orientation is used.

The ferroelectric film 34 is comprised of a ferroelectric material having a perovskite-type crystal structure that is expressed by a general formula of A B O₃. The element A in the general formula may be Pb or Pb having a part thereof replaced with La, Ca or Sr. The element B may be Zr or Ti. Moreover, at least one of V (vanadium), Nb (niobium), Ta, Cr (chrome), Mo (molybdenum), W (tungsten), Ca (calcium), Sr (strontium) and Mg (magnesium) may be added. As a ferroelectric material composing the ferroelectric film 34, a known material, such as, for example, PZT, SBT, and (Bi, La)₄ Ti₃ O₁₂ (bismuth lanthanum titanate: BLT) can be used. Above all, PZT may preferably be used.

When PZT is used as the ferroelectric material, the content of Ti in the PZT may preferably be made greater than the content of Zr in order to obtain a greater amount of spontaneous polarization. Moreover, when the content of Ti in the PZT is greater than the content of Zr therein, the crystal orientation of the PZT may preferably be in a (111) orientation, because the hysteresis characteristic of the PZT is favorable in this orientation.

The upper electrode 35 is electrically connected to a ground line (not shown) in the present example, and may be formed in a single layer film or a multilayer film of a plurality of laminated layers. As the material for the upper electrode 35, any of the aforementioned materials used for the lower electrode 33 described above, or Al (aluminum), Ag (silver), or Ni (nickel) may be used. Also, in the present example, the upper electrode 35 is composed of a multilayer film of iridium oxide and iridium, whereby the upper electrode 35 can enhance the adhesion with the ferroelectric film 34, and function as an oxygen barrier film with respect to a portion on the side of the ground line.

With the structure described above, upon application of a voltage to the gate electrode 222 of the transistor 22, an electric field is applied across the source region 223 and the drain region 224, thereby turning on the channel, and a current can be circulated through the channel. When the channel is turned on, an electrical signal provided through the bit line electrically connected to the source region 223 is transmitted to the drain region 224, and further transmitted to the lower electrode 33 of the ferroelectric capacitor 3 that is electrically connected to the drain electrode 224. As a result, a voltage can be applied across the upper electrode 35 and the lower electrode 33 of the ferroelectric capacitor 3, whereby a charge (data) can be stored in the ferroelectric film 34. In this manner, by switching electrical signals to the ferroelectric capacitor 3 with the transistor 22, data (charge) can be read out or written in the ferroelectric memory device 1.

Method For Manufacturing Ferroelectric Memory Device

Next, a method for manufacturing a ferroelectric memory device in accordance with an embodiment of the invention is described. In the present embodiment, a method for manufacturing the ferroelectric memory 1 is described as an example.

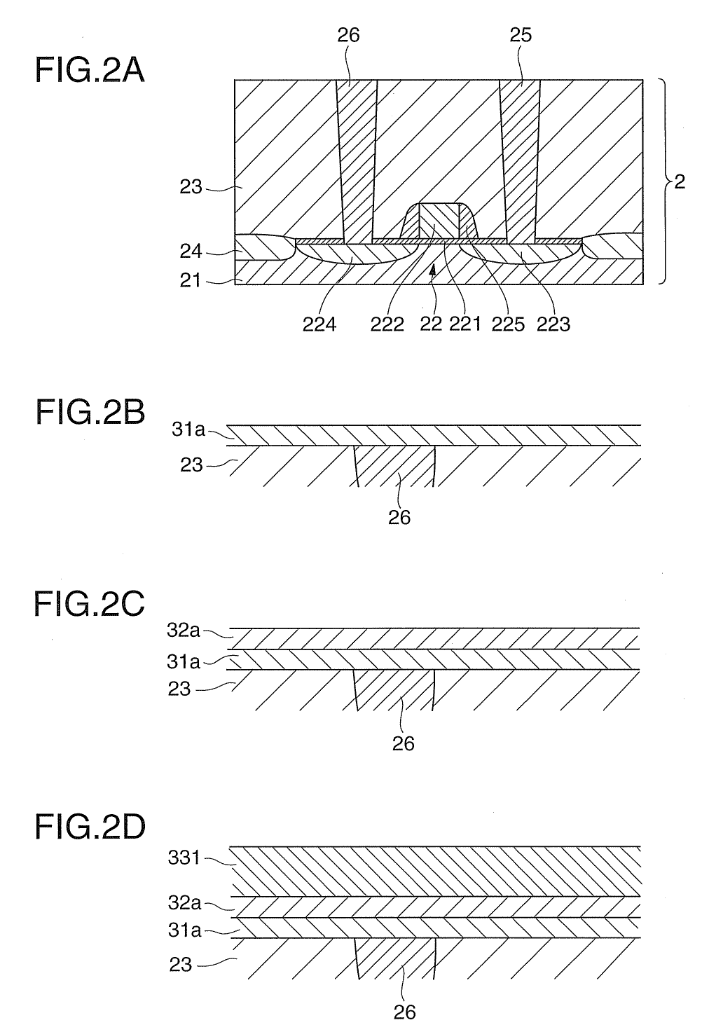

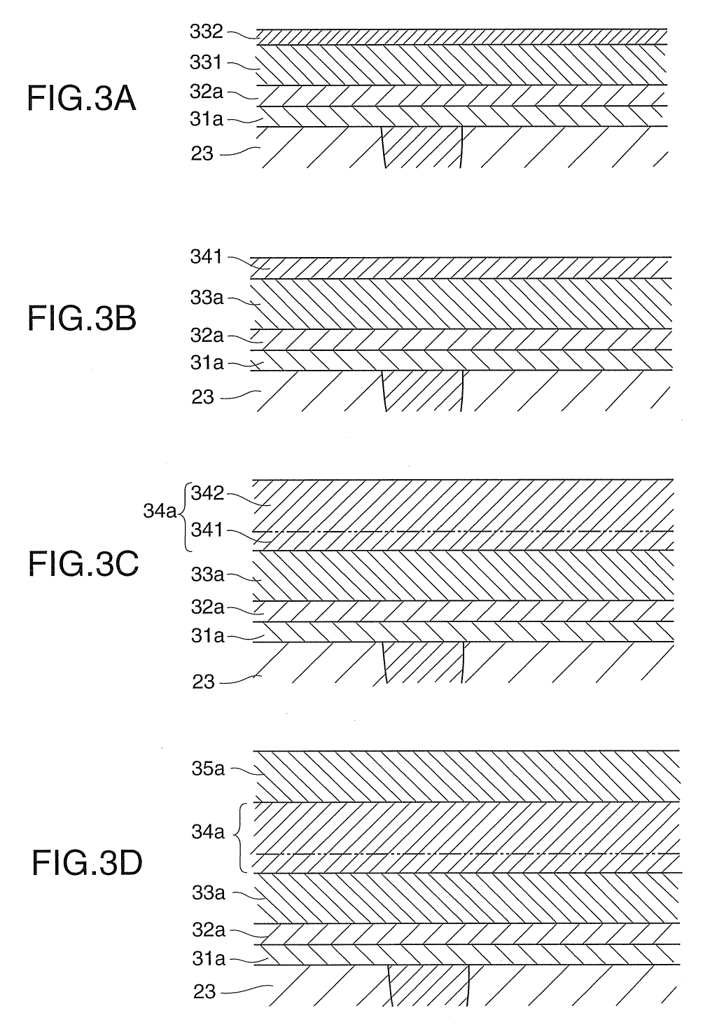

FIGS. 2A-2D and FIGS. 3A-3D are cross-sectional views showing steps of the method for manufacturing the ferroelectric memory 1 in accordance with an embodiment of the invention. It is noted that, in the figures used for the following description, the main portion is schematically illustrated in enlargement.

First, as shown in FIG. 2A, a base substrate 2 may be formed, using a known method. More specifically, for example, element isolation regions 24 are formed in a silicon substrate (substrate) 21 by a LOCOS method, a STI method or the like, and a gate dielectric film 221 is formed by a thermal oxidation method on the silicon substrate 21 between the element isolation regions 24. Then, a gate electrode 222 comprised of polycrystal silicon or the like is formed on the gate dielectric film 221. Doped regions 223 and 224 are formed by implanting impurities in a surface layer of the silicon substrate 21 between the element isolation regions 24 and the gate electrode 222. Then a sidewall 225 is formed by using an etch-back method or the like. In accordance with the present embodiment, the doped region 223 is functioned as a source region, and the doped region 224 is functioned as a drain region.

Then, a film of SiO₂ is formed by, for example, a CVD method, thereby forming a base dielectric film 23 on the silicon substrate 21 where the transistor 22 is formed. Then, the base dielectric film 23 on the source region 223 and on the drain region 224 is etched, thereby forming a through hole that exposes the source region 223 and a through hole that exposes the drain region 224. Films of, for example, Ti and TiN are formed in the through holes by a sputter method, thereby forming adhesion layers (not shown).

Then, a film of tungsten is formed by, for example, a CVD method over the entire surface of the base dielectric film 23 including inside the through holes, thereby embedding tungsten in the through holes, and a portion of tungsten above the base dielectric film 23 is polished by a CMP method or the like, whereby tungsten on the base dielectric film 23 is removed. In this manner, a first plug 25 is embedded in the through hole over the source region 223, and a second plug 26 is embedded in the through hole over the drain region 224. The base substrate 2 is formed according to the steps described above.

Next, a ferroelectric capacitor 3 is formed (manufactured) on the base dielectric film 23. First, as shown in FIG. 2B, a conductive film 31a is formed on the base dielectric film 23. More specifically, a film of Ti is formed on the base dielectric film 23 by using, for example, a CVD method or a sputter method. It is noted that Ti has a high level of self-orientation property, and therefore forms a layer in a hexagonal close-packed structure having a (001) crystal orientation. Then, for example, a nitrization treatment in which a heat treatment is applied to the film in a nitrogen atmosphere (for example, at 500° C. or higher but 650° C. or lower) is conducted, thereby forming a conductive film 31a composed of TiN. By setting the heat treatment temperature at 650° C. or lower, its influence to the characteristics of the transistor 22 can be controlled, and by setting the heat treatment temperature at 500° C. or higher, the nitrization treatment can be shortened. It is noted that, the conductive film 31a thus formed has a (111) crystal orientation as the crystal orientation of Ti in an original metal state is reflected therein.

Next, as shown in FIG. 2C, a film of TiAlN is formed on the conductive film 31a by, for example, a sputter method or a CVD method, thereby forming an oxygen barrier film 32a. By forming the oxygen barrier film 32a to have a crystal orientation that matches with the crystal orientation of the conductive film 31a that serves as its base, the oxygen barrier film 32a can be formed epitaxial-like. In other words, the oxygen barrier film 32a in a (111) crystal orientation that reflects the crystal orientation of the conductive film 31a can be formed.

Next, as shown in FIG. 2D, a film of iridium is formed on the oxygen barrier film 32a by a sputter method or the like, thereby forming an iridium film (electrode film) 331. The iridium film 331 can be formed while reflecting the crystal orientation of the base layer, like the oxygen barrier film 32a. As the oxygen barrier film 32a has a (111) crystal orientation, the iridium film 331 can be formed in a (111) crystal orientation.

Next, the surface layer of the iridium film 331 is subjected to a heat treatment for thermal oxidation, thereby forming an iridium oxide (oxidized electrode layer) 332, as shown in FIG. 3A.

According to a method in related art, the thermal oxidation is conducted in a MOCVD apparatus chamber under a condition similar to the condition for forming a ferroelectric film, more specifically, under a condition in which the pressure within the chamber is reduced to several (Torr), and a heat treatment is conducted for several minutes. Under such condition, the oxygen partial pressure is low and the heat treatment time is not sufficient, such that oxidation of the electrode film becomes non-uniform. As a result, the volume expansion due to oxidation becomes non-uniform such that protrusions (hillocks) in colonies are formed on the oxidized electrode layer, which causes deterioration of the characteristics of a ferroelectric film formed on the oxidized electrode layer.

Accordingly, to examine thermal oxidation conditions that do not cause hillocks, the inventors conducted experiments while changing the oxygen partial pressure Po₂ defined by Formula Po₂=(p/760)·(fo₂/fₜₒₜₐₗ)·100, where p is the pressure inside the chamber (Torr), fo₂ is the flow quantity of oxygen gas supplied to the chamber (sccm), and fₜₒₜₐₗ is the total amount of gases supplied to the chamber (sccm). The results are explained below.

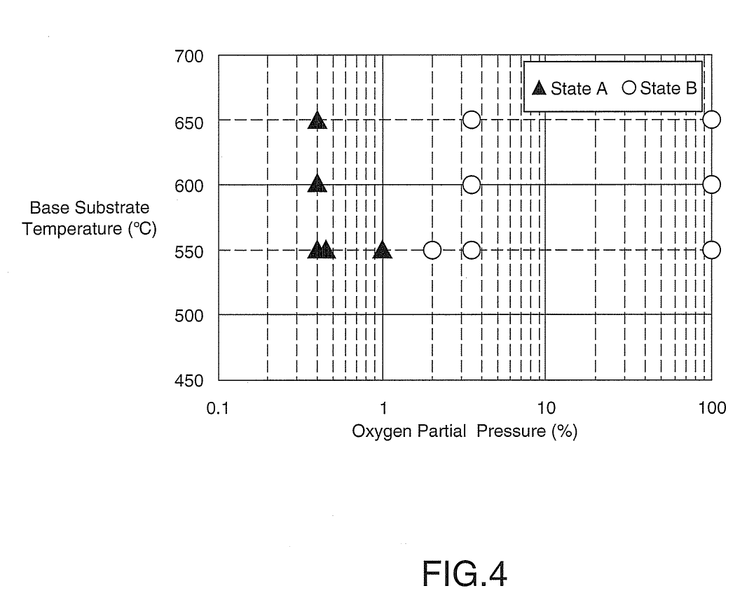

FIG. 4 is a graph showing relations between oxygen partial pressures and generation of hillocks. FIG. 4 shows data that were obtained from ferroelectric capacitors manufactured through conducting a heat treatment (rapid thermal annealing: RTA) for one minute to each base substrate by a lamp anneal method, thereby thermally oxidizing the electrode film. Oxygen partial pressures at the time of heat treatment are plotted along the horizontal axis, and heating temperatures for heating each base substrate are plotted along the vertical axis. Also, State A shown in FIG. 4 indicates a state in which hillocks are generated, and State B indicates a state in which hillocks are not generated. It is observed from the results shown in FIG. 4 that hillocks are not generated when the oxygen partial pressure is 2% or higher.

When the thermal oxidation is conducted in a MOCVD apparatus chamber, the oxygen partial pressure is normally about 0.4%, and the heating temperature is about 600° C., it is understood that hillocks would more likely occur than those shown in the graph of FIG. 4. Normally, the pressure p within the chamber is set to several Torr (for example, 4 Torr), and therefore it is understood from the formula of oxygen partial pressure that (p/760) is about 0.0053, and (fo₂/fₜₒₜₐₗ) is less than 1. Accordingly, the oxygen partial pressure cannot be set higher than about 0.53%. In this respect, the inventor conceived that the pressure p within the chamber could be increased to increase the oxygen partial pressure.

In view of the above, in accordance with the invention, the surface layer of the iridium film 331 is subjected to a heat treatment in an atmosphere of atmospheric-pressure with an oxygen partial pressure being 2% or higher, thereby thermally oxidizing the surface layer. As a heat treatment apparatus for the heat treatment, a furnace, such as, for example, a resistance heating type diffusion furnace, an anneal furnace, an oxidation furnace and an electric furnace, an infrared ray heating type lamp anneal apparatus and the like can be used. In accordance with the present embodiment, the surface layer of the iridium film 331 is thermally oxidized by furnace annealing (heat treatment) using an electric furnace. The electric furnace is a heat treatment apparatus that is equipped with a chamber having a retaining section that is capable of retaining (mounting) an object, a gas supply device that supplies gas in the chamber, and a heating device such as heaters for heating the atmosphere within the chamber.

It is noted that, in accordance with the method of the invention, the thermal oxidation is conducted in an atmosphere of atmospheric-pressure, and therefore the chamber does not need to have a structure that is capable of enduring extreme low pressures near vacuum, and thus an electric furnace, a lamp anneal apparatus or the like equipped with a large-sized chamber can be used. By using an electric furnace, a lamp annealing apparatus or the like equipped with a large-sized chamber, about several ten to several hundred wafers (base substrates 2) can be thermally treated in a batch.

For thermally oxidizing the surface layer of the iridium film 331 by using such an electric furnace, the base substrate 2 on which the iridium film 331 is formed is retained in the chamber. Then, by using a gas supply device, a mixed gas of, for example, oxygen gas and argon gas is supplied in the chamber. The amount of oxygen gas and argon gas to be supplied may be set such that the pressure inside the chamber is generally at the same level as that of the air atmosphere, and the oxygen partial pressure is 2% or higher, in other words, the pressure p within the chamber is about 760 (Torr), and the value of fo₂/fₜₒₜₐₗ may be set to 0.02 or higher.

In accordance with the embodiment of the invention, oxygen gas alone is supplied and the oxygen partial pressure is set at about 100%, and the atmosphere within the chamber is heated to about 550° C. to about 650° C. by the heater. Under the foregoing condition, the surface layer of the iridium film 331 is subjected to a heat treatment for 40 minutes thereby thermally oxidizing the surface layer, whereby an iridium oxide layer 332 is formed to a thickness of 30 nm or less. In this manner, by setting the oxygen partial pressure to about 100% and heating at 550° C. or higher, the surface layer of the iridium 331 can be sufficiently and uniformly, thermally oxidized, and the iridium oxide layer 332 can be formed flat without generating hillocks. Also, by heating at 650° C. or lower, adverse effects by the heat on the transistor 22 (see FIG. 1) can be almost entirely eliminated.

Next, as shown in FIG. 3B, an initial film 341 of a ferroelectric film 34 is formed on the iridium film 331 by using a MOCVD method that reacts source material gas for the ferroelectric film 34 with oxygen gas. In accordance with the present embodiment, the initial film 341 is formed by using a MOCVD apparatus. The MOCVD apparatus is an apparatus equipped with a film forming chamber that contains the base substrate 2, a suscepter disposed in the film forming chamber for mounting the base substrate 2, a shower head for supplying gas in the film forming chamber, and a heater lamp device for heating the base substrate 2 mounted in the film forming chamber.

To form the initial film 341 by using such a MOCVD apparatus, first, the base substrate 2 on which the iridium oxide layer 332 is formed is mounted on the suscepter. Then, source material gas for the ferroelectric film 34 and oxygen gas are supplied in the film forming chamber through the shower head, and the base substrate 2 is heated to about 550° C. to about 650° C. from its lower surface side by the heating lamp.

In accordance with the present embodiment, as the source material gas, for example, a mixed gas of Pb (DIBM) [Pb (C₉H₁₅O₂)₂: lead bis(diisobutyl methanate)], Zr (DIBM) [Zr (C₉H₁₅O₂)₂: zirconium(diisobutyl methanate)], and Ti (Oi Pr)₂ (DPM)₂ [Ti (O-i-C₃H₇)₂ (C₁₁H₁₉O₂)₂: titanium(diisopropoxy)(dipivaloylmethanate)] is used. As the source material gas, other materials, such as, Pb (DPM)₂ [Pb (C₁₁H₁₉O₂)₂: lead(dipivaloylmethanate)], Zr (IBPM)₄ [Zr (C₁₀H₁₇O₂)₂: zirconium tetrakis(isobutyl pivaloylmethanate)], and Ti (Oi Pr)2 (DPM)₂ may be used.

Also, oxygen gas is supplied in an amount smaller than (for example, 0.1 times or greater but 1.0 times or smaller) the amount necessary for reaction of the source material gas. In other words, when the organic compositions of the source material gas such as carbon and hydrogen are burnt, metal compositions (Pb, Zr, Ti) of the source material gas are separated, and these metal compositions are oxidized and crystallized into PZT. At this time, an amount of oxygen gas smaller than the sum of the amount of oxygen gas necessary for burning the organic compositions and the amount of oxygen gas necessary for oxidizing the metal compositions is supplied. Such an amount of oxygen gas can be calculated from the amount of source material gas to be supplied.

As a result, as the amount of oxygen supplied is smaller than the amount of oxygen necessary for reaction of the source material gas, the formation of the initial film 341 progresses, while depriving oxygen from the iridium oxide layer 332, in other words, reducing iridium oxide of the iridium oxide layer 332. As the base substrate 2 is heated at temperatures at which the reduced iridium can crystallize (for example, 550° C. to 650° C.), the reduced iridium re-crystallize on the iridium film 331. As the thickness of the iridium oxide layer 332 (see FIG. 3A) is 30 nm or less, as described above, the reduced iridium can succeed the crystal orientation of the iridium film 331 having a (111) crystal orientation, which can be reflected in the growth direction of the initial film 341. As a result, the initial film 341 can be formed in a (111) crystal orientation, and the iridium film 331 including the portion of the reduced and re-crystallized iridium oxide layer 332 becomes a lower electrode 33a. No hillocks are generated in the iridium oxide layer 332, as described above, such that the initial film 341 with a favorable crystal orientation can be formed on the flat iridium oxide layer 332.

Next, as shown in FIG. 3C, a core film 342 is formed on the initial film 341. More specifically, after forming the initial film 341, the base substrate 2 is kept disposed on the suscepter of the MOCVD apparatus. Then, source material gas for the ferroelectric film 34 and oxygen gas are supplied in the film forming chamber through the shower heads, respectively, and the base substrate 2 is heated from its lower surface side by the heater lamps at about 450° C. to about 550° C.

It is noted that the amount of oxygen gas is set to be greater than the amount necessary for reaction of the aforementioned source material gas. As the initial film 341 is formed with a favorable crystal orientation and has a (111) crystal orientation as described above, the core film 342 can be formed epitaxial-like thereon, such that the core film 342 can be formed in a (111) crystal orientation. Also, as the oxygen gas is supplied in an amount greater than the amount necessary for reaction of the source material gas, the core film 342 can be formed without generating oxygen deficiencies. Also, by setting the heating temperature lower than the temperature at which the initial film 341 is formed, thermal influence on the transistor 22 (see FIG. 1) can be reduced. In this manner, a ferroelectric film 34a composed of the initial film 341 and the core film 342 is formed.

Next, as shown in FIG. 3D, an upper electrode layer 35a comprised of metal materials, such as, Pt, iridium oxide, iridium and the like is formed on the ferroelectric film 34a by, for example, a sputter method or a CVD method.

Next, the conductive film 31a, the oxygen barrier film 32a, the lower electrode layer 33a, the ferroelectric film 34a, and the upper electrode layer 35a are patterned by using known resist technique and photolithography technique, thereby forming (manufacturing) a ferroelectric capacitor 3. In this manner, the ferroelectric memory 1 shown in FIG. 1 is manufactured.

### Embodiments Examples

Next, characteristics of ferroelectric capacitors obtained by the manufacturing method of the embodiment described above are described, in comparison with ferroelectric capacitors obtained by a manufacturing method of related art.

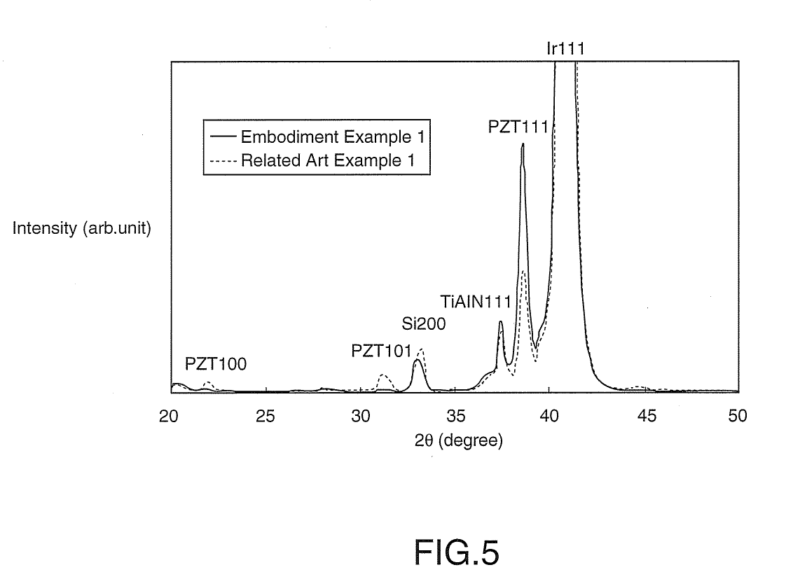

FIG. 5 is a graph showing X-ray diffraction patterns of an embodiment example 1 obtained by the manufacturing method in accordance with the present embodiment, and a related art example 1 obtained by a manufacturing method of related art. The embodiment example 1 was manufactured by a heat treatment conducted in an atmosphere with its oxygen partial pressure being about 100% by furnace annealing at temperatures of about 600° C. for 40 minutes. The related art example 1 was manufactured by a heat treatment conducted in an atmosphere with its oxygen partial pressure being about 0.4% within a MOCVD apparatus chamber at temperatures of about 600° C. for 4 minutes, and then heat treated at about 620° C.

As shown in FIG. 5, the related art example 1 contains PZT with a (100) crystal orientation and a (101) crystal orientation, while the embodiment example 1 hardly contains any PZT that does not have any contribution or has a small contribution to the amount of polarization. Also, the embodiment example 1 contains PZT with a favorable (111)-orientation substantially more than the related art example 1. In this manner, by the effect of the invention, it is understood that the ferroelectric film (PZT) can be formed in a (111) preferred crystal orientation.

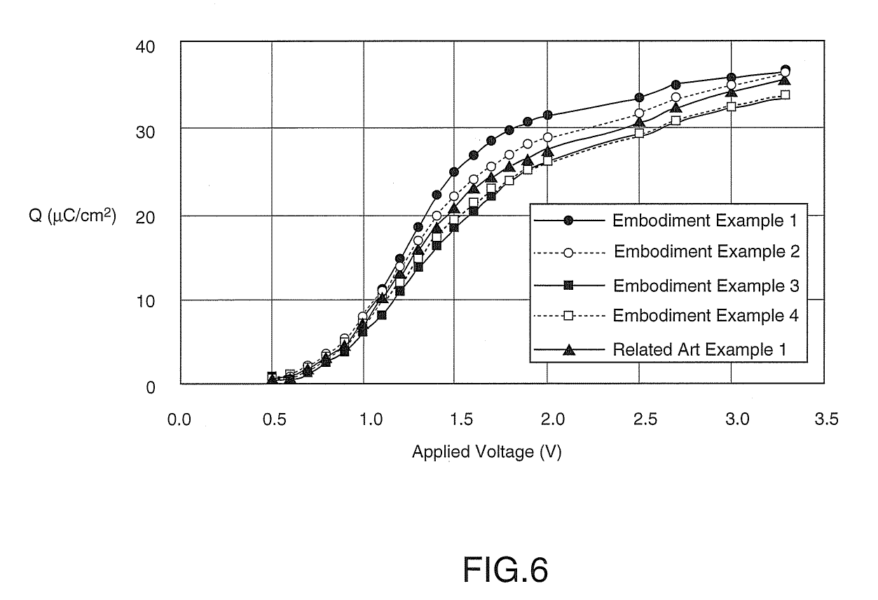

FIG. 6 is a graph showing electrical characteristics of embodiment examples 1-4 obtained by the manufacturing method of the present embodiment and a related art example 1 obtained by a manufacturing method of related art, wherein voltages applied between the upper electrode and the lower electrode are plotted along the horizontal axis and amounts of charge stored in the ferroelectric film are plotted along the vertical axis. The embodiment example 1 and the embodiment example 2 were manufactured by a heat treatment conducted in an atmosphere with its oxygen partial pressure being about 100% by furnace annealing for 40 minutes, wherein the heating temperature for the embodiment example 1 was about 600° C. and the heating temperature for the embodiment example 2 was about 550° C. The embodiment example 3 and the embodiment example 4 were manufactured by a heat treatment conducted in an atmosphere with its oxygen partial pressure being about 100% by lamp annealing for 1 minute, wherein the heating temperature for the embodiment example 3 was about 600° C. and the heating temperature for the embodiment example 4 was about 650° C. The related art example 1 was manufactured with the same condition described above. It is understood from FIG. 6 that the embodiment example 1 stores a greater amount of charge per applied voltage, compared to the related art example 1, and has excellent electrical characteristics. Also, it is understood that the embodiment examples 2-4 have electrical characteristics similar to those of the related art example 1.

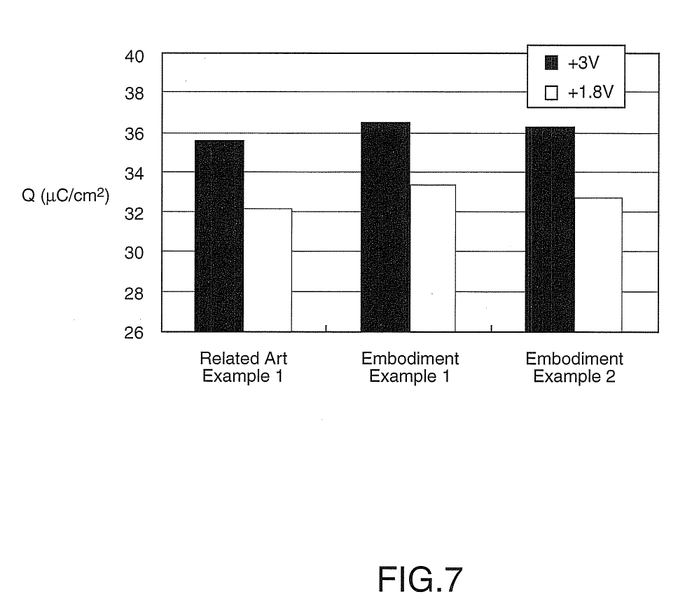

FIG. 7 is a graph for quantitatively comparing the electrical characteristics of the embodiment examples 1 and 2 and the related art example 1, and indicates the amounts of charge stored in the ferroelectric film at applied voltages 1.8V and 3.0V, respectively. It is understood that the embodiment examples 1 and 2 store a greater amount of charge at both of the applied voltages of 1.8V and 3.0V, compared to the related art example 1, and thus have excellent electrical characteristics.

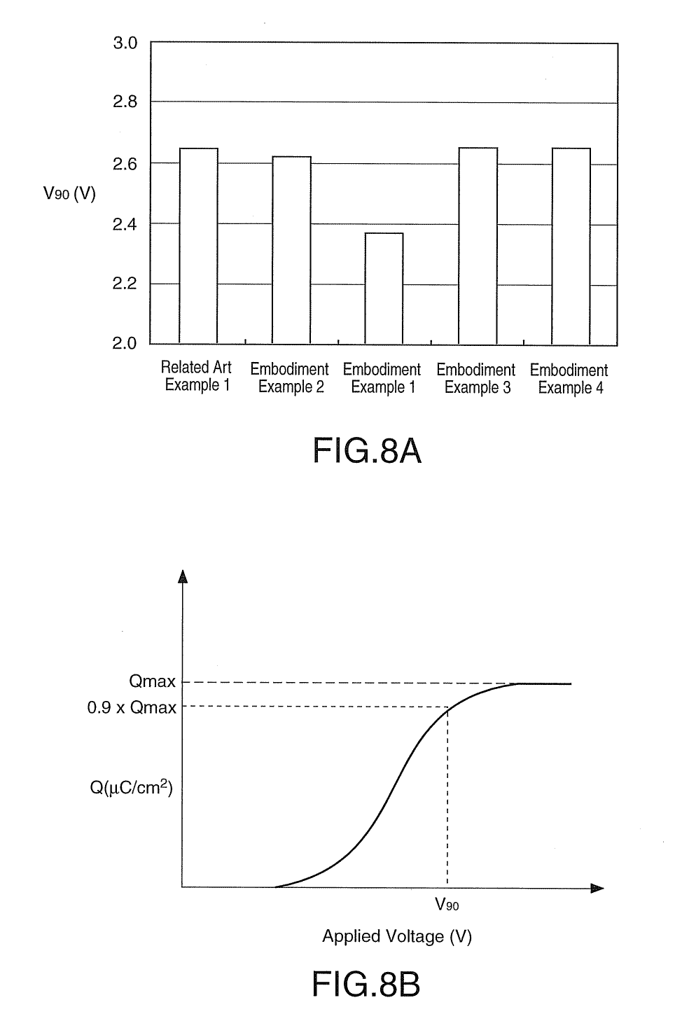

FIG. 8A is a graph showing saturation characteristics of the embodiment examples 1-4 and the related art example 1, and FIG. 8B is a scheme for describing the definition of saturation characteristic. First, an index V₉₀ indicating the saturation characteristic is described. As shown in FIG. 8B, the amount of stored charge with respect to an applied voltage becomes saturated when the applied voltage reaches a certain level. When the saturation amount of stored charge is Qmax, V₉₀ is an application voltage that is required to store an amount of charge that is equal to 90% of Qmax. The ferroelectric capacitor can be functioned at a lower voltage with a lower value of V₉₀, which means excellent responsiveness. It is understood from FIG. 8A that the embodiment example 1 excels in saturation characteristic considerably better than the related art example 1. The embodiment example 2 has also better saturation characteristic than that of the related art example 1. It is therefore understood that the heat treatment by furnace annealing conducted at heating temperatures of 550° C. or higher can result in improved saturation characteristics compared to the related art example 1. It is also observed that the embodiment examples 3 and 4 have saturation characteristics at about the same level of the related art example 1.

According to the method of the present embodiment, the iridium film (electrode film) 331 is thermally oxidized in an atmosphere of atmospheric-pressure. Therefore the heat treatment can be conducted in a large-sized chamber, and many base substrates 2 (wafers) on which iridium films 331 are formed can be heat-treated in a batch. Therefore, ferroelectric memory devices 1 can be very efficiently manufactured. Also, as the oxygen partial pressure is set to 2% or greater, hillocks are prevented from being generated on the iridium oxide layer (oxidized electrode layer) 332, ferroelectric films 34 with a favorable crystal orientation can be formed, and favorable ferroelectric capacitors 3 and ferroelectric memory devices 1 equipped with the ferroelectric capacitor 3 can be manufactured.

Also, as furnace annealing is used for the heat treatment for thermally oxidizing the iridium film 331, the degree of freedom in setting the conditions such as heating time and the like is improved. Therefore, for example, by conducting a heat treatment in an atmosphere having an oxygen partial pressure being 100% for about 40 minutes, ferroelectric capacitors 3 with very favorable electrical characteristics and saturation characteristics can be manufactured. Even when the heat treatment is conducted for 40 minutes, several ten to several hundred wafers can be heat-treated in a batch, such that the manufacturing efficiency can be improved, compared to the case where each wafer is heat-treated for about 4 minutes by a MOCVD apparatus. Also, by using a lamp annealing apparatus, ferroelectric capacitors having characteristics at about the same level of those manufactured by a MOCVD apparatus can be manufactured by lamp annealing for about one minute, and numerous wafers can be heat-treated, whereby the manufacturing efficiency can be considerably improved.

What is claimed is:

1. A method for manufacturing a ferroelectric capacitor having a ferroelectric film interposed between a first electrode and a second electrode, the method comprising the steps of:
forming an electrode film above a substrate;
thermally oxidizing a surface layer of the electrode film to form an oxidized electrode layer in an atmosphere of atmospheric-pressure with an oxygen partial pressure being 2% or grater;
forming a ferroelectric film on the electrode layer by a MOCVD method thereby forming a first electrode composed of the electrode film including the oxidized electrode layer that serves as a base for the ferroelectric film; and
forming a second electrode on the ferroelectric film.

2. A method for manufacturing a ferroelectric capacitor according to claim 1, wherein in the step of forming a ferroelectric film, the ferroelectric film is formed by using a MOCVD method that reacts source material gas for the ferroelectric film and oxygen gas, wherein an initial film is formed in an atmosphere that contains the oxygen gas in an amount less than an amount necessary for reaction of the source material gas, and then a core film is formed in an atmosphere that contains the oxygen gas in an amount greater than an amount necessary for reaction of the source material gas, thereby forming the ferroelectric film composed of the initial film and the core film.

3. A method for manufacturing a ferroelectric capacitor according to claim 1, wherein, in the step of forming an electrode film, the electrode film is formed to have a (111) crystal orientation.

4. A method for manufacturing a ferroelectric capacitor according to claim 1, wherein, in the step of forming an electrode film, the electrode film is formed from iridium.

5. A method for manufacturing a ferroelectric capacitor according to claim 1, wherein, in the step of forming a ferroelectric film, the ferroelectric film composed of Pb (Zr, Ti) O₃ is formed.

6. A method for manufacturing a ferroelectric capacitor according to claim 1, wherein the step of thermally oxidizing is conducted by furnace annealing.

7. A method for manufacturing a ferroelectric capacitor according to claim 6, wherein the surface layer of the ferroelectric film is heated to 550° C. or higher in an oxygen atmosphere.

8. A method for manufacturing a ferroelectric capacitor according to claim 1, wherein, in the thermal oxidation step, the oxidized electrode layer is formed to a thickness of 30 nm or less.

9. A method for manufacturing a ferroelectric memory device equipped with a ferroelectric capacitor and a transistor that switches an electrical signal to be transmitted to the ferroelectric capacitor, wherein the ferroelectric capacitor is manufactured by the method for manufacturing a ferroelectric capacitor recited in claim 1.
